(19) United States
(12) Patent Application Publication
(10) Pub. No.: US 2012/0019455 A1
(43) Pub. Date: Jan. 26, 2012

(54) TOUCH SCREEN PANEL AND METHOD OF MANUFACTURING THE SAME

(75) Inventors: Yong Hyun Jin, Seoul (KR); Dae Jun Kim, Gyunggi-do (KR)

(73) Assignee: SAMSUNG ELECTRO-MECHANICS CO., LTD., Gyunggi-do (KR)

(21) Appl. No.: 12/943,201

(22) Filed: Nov. 10, 2010

(30) Foreign Application Priority Data
Jul. 26, 2010 (KR) 1020100072015

(51) Int. Cl. G06F 3/041; H05K 13/00

(52) U.S. Cl. 345/173; 29/592.1

(57) ABSTRACT

Disclosed herein is a touch screen panel. The touch screen panel includes a substrate, a plurality of first detection patterns, a plurality of second detection patterns, and a plurality of connection prevention layers. Each of the first detection patterns includes a plurality of first detection cells arranged in a single column and a plurality of first connection lines configured to connect first detection cells which are adjacent to each other. Each of the second detection patterns includes a plurality of second detection cells arranged in a single row and a plurality of second connection lines configured to connect second detection cells which are adjacent to each other. Each of the connection prevention layers is located between each of the first connection lines and each of the second connections line at the intersection thereof, and is made of an electrical insulation material.

### CROSS REFERENCE TO RELATED APPLICATION

This application claims the benefit of Korean Patent Application No. 10-2010-0072015, filed on Jul. 26, 2010, entitled “Touch Screen Panel and Manufacturing Method thereof,” which is hereby incorporated by reference in its entirety into this application.

### BACKGROUND OF THE INVENTION

1. Technical Field

The present invention relates to a touch screen panel and a method of manufacturing the same.

2. Description of the Related Art

Touch screen panels are input devices which enable user commands to be input by selecting instructions displayed on the screens of image display devices using the hand of a human or an object.

For this purpose, such a touch screen panel is provided on the front face of an image display device and converts information about a contact point in direct contact with the hand of a human or with an object into an electrical signal. Here, an instruction selected at the contact point is received as an input signal. Since a touch screen panel can replace a separate input device, such as a keyboard or a mouse, which is connected to an image display device and then operates, the utilization range of touch screen panels has tended to become wider.

Touch screen panels are classified into resistive touch screen panels, optical sensing touch screen panels, and capacitive touch screen panels according to methods of implementing touch screen panels.

Capacitive touch screen panels convert information about a contact point into an electrical signal by sensing the variation in capacitance formed between a conductive detection pattern and another adjacent detection pattern or a ground electrode when the hand of a human or an object comes in contact with the contact point.

Here, in order to clearly determine a contact point on a contact surface, the detection pattern is configured to include first detection patterns (X patterns) connected along a first direction and second detection patterns (Y patterns) connected along a second direction.

The above-described first and second detection patterns are generally located in the same layer. In this case, detection patterns arranged on the same X or Y line are connected to each other by forming separate connection patterns using contact holes formed in the upper insulation film thereof.

Here, the connection patterns are formed of transparent conductive materials, such as the first and second detection patterns. Therefore, since a mask process should be added in order to form the connection patterns, there arises the problem of the number of masks increasing and the process thereof becoming complicated.

Further, the first or second detection patterns are electrically connected by the separate connection patterns, and, in this case, the first and second detection patterns intersect one another at regions where the connection patterns are formed.

Here, the width of each of the connection patterns is generally minimized in order to reduce the influence of parasitic capacitance generated due to the connection pattern. On the contrary, when the width of the connection pattern is narrow, line resistance raises, so that there is a problem of sensing sensitivity decreasing.

In particular, the resistance of the transparent conductive materials, which realize the first and second detection patterns and the connection patterns, is high, so that the increase in line resistance, generated when the width of the connection pattern is reduced, greatly affects the decrease in sensing sensitivity.

### SUMMARY OF THE INVENTION

Accordingly, the present invention has been made keeping in mind the above problems occurring in the prior art, and the present invention is intended to provide a touch screen panel and a method of manufacturing the same which prevent a decrease in sensing sensitivity with regard to first detection patterns and second detection patterns which are formed on the same layer by removing a mask process of forming connection patterns which connect the first and second detection patterns and by reducing parasitic capacitance at an intersection.

In accordance with an aspect of the present invention, there is provided a touch screen panel, including: a substrate; a plurality of first detection patterns, each formed on the substrate, configured to include a plurality of first detection cells which are arranged in a single column along a first direction having a same coordinate, and a plurality of first connection lines which connect first detection cells which are adjacent to each other; a plurality of second detection patterns, each formed on the substrate, configured to include a plurality of second detection cells which are arranged in a single row along a second direction having a same coordinate, and a plurality of second connection lines which connect second detection cells which are adjacent to each other; and a plurality of connection prevention layers, each located between each of the first connection lines and each of the second connection lines at an intersection where the first connection line of the first detection pattern intersects the second connection line of the second detection pattern, and each made of an electrical insulation material.

Further, the connection prevention layer of the present invention includes: a first adhesive layer formed to enclose the first connection line and made of a non-conductive adhesive material; and an insulation layer layered on the first adhesive layer, and configured to have a surface on which the second connection line is formed and which is away from a surface which comes into contact with the first adhesive layer.

Further, the second connection line of the present invention includes: a bridge-shaped bridge connection line formed to enclose the connection prevention layer; and a coupling line configured to have one end which is connected to the bridge connection line and another end which is connected to one of the second detection cells.

Further, the present invention further includes a second adhesive layer configured to attach the bridge connection line to the coupling line with conductivity.

Further, the second detection cells of the present invention are alternately arranged with the first detection cells so that each of the second detection cells is not superimposed on the corresponding first detection cell.

Further, the first and second detection patterns of the present invention are made of a transparent electrode material.

Further, the transparent electrode of the present invention is made of a conductive polymer.

Further, a method of the present invention includes: (A) preparing a substrate configured to include a plurality of first detection cells, a plurality of first connection lines connecting first detection cells which are adjacent to each other, and a plurality of second detection cells which are alternately arranged with the first detection cells; (B) preparing a plate-shaped transporter configured to include a plurality of connection prevention layers separated at a predetermined interval from each other, and formed at locations corresponding to the respective first connection lines; (C) layering the connection prevention layers of the transporter on the respective first connection lines of the substrate; and (D) forming a plurality of second connection lines each configured to connect second detection cells so that the second connection line intersects the corresponding first connection line with each of the connection prevention layers being interposed therebetween.

Further, the (B) of preparing the transporter of the present invention includes: (B-1) preparing the plate-shaped transporter; (B-2) layering a plurality of insulation layers on the transporter, the insulation layers constituting the connection prevention layer which is formed in the plate shape, separated at the predetermined interval from each other, and formed at a location corresponding to the first connection line; and (B-3) forming a plurality of adhesive layer on the insulation layers, the adhesive layers constituting the connection prevention layer.

Further, the (C) of layering the connection prevention layers of the present invention includes: (C-1) allowing the connection prevention layer of the transporter to face the corresponding first connection line of the substrate; (C-2) layering the connection prevention layer of the transporter on the first connection line of the substrate; and (C-3) removing the transporter.

Further, a method of the present invention includes: (A) preparing a substrate configured to include a plurality of first detection cells, a plurality of first connection lines connecting the first detection cells which are adjacent to each other, and a plurality of second detection cells being alternately arranged with the first detection cells and including conjunctive lines which protrude toward each other;
(B) preparing a transporter configured to include a plurality of bridge connection lines, each of the bridge connection lines being formed in a bridge shape and having a depression, being separated at a predetermined interval from each other, including a connection prevention layer on the depression, and being formed at a location corresponding to each of the first connection lines; and (C) layering the connection prevention layer of the transporter on the first connection line of the substrate, and connecting the bridge connection line to the corresponding conjunctive line with the bridge connection line enclosing the connection prevention layer.

Further, the (B) of preparing the transporter of the present invention includes: (B-1) preparing the plate-shaped transporter; (B-2) layering the plurality of bridge connection lines on the transporter, each of the bridge connection lines being formed in the bridge shape, being separated at the predetermined interval from each other, being formed at the location corresponding to the first connection line, and having the depression; (B-3) forming an insulation layer constituting the connection prevention layer in the depression of the bridge connection line; (B-4) forming an adhesive layer constituting the connection prevention layer on the insulation layer; and (B-5) forming conductive adhesive layers on both ends of the bridge connection line.

Further, the (C) of layering the connection prevention layer of the present invention includes: (C-1) allowing the connection prevention layer of the transporter to face the corresponding first connection line of the substrate; (C-2) layering the connection prevention layer of the transporter on the first connection line of the substrate so that the bridge connection line is connected to the conjunctive line with the bridge connection line enclosing the connection prevention layer; and (C-3) removing the transporter.

Herein, terms and words used in the present specification and claims should not be interpreted as common and dictionary meanings but should be interpreted as having meanings and concepts in conformity with the technical spirit of the present invention based on the principle in which an inventor can appropriately define the concepts denoted by terms in order to describe the inventor's own invention in the most appropriate way.

### BRIEF DESCRIPTION OF THE DRAWINGS

The above and other objects, particular advantages, and new features of the present invention will be more clearly understood from the following detailed description and preferred embodiments below taken in conjunction with the accompanying drawings, in which:

FIG. 1 is a plan view of a touch screen panel according to a first embodiment of the present invention;

FIG. 2 is a sectional view taken along line A-A′ of FIG. 1;

FIG. 3 is a plan view of a touch screen panel according to a second embodiment of the present invention;

FIG. 4 is a sectional view taken along line B-B′ of FIG. 3;

FIGS. 5 to 8 are views showing the process of a method of manufacturing the touch screen panel according to the first embodiment of the present invention; and

FIGS. 9 to 12 are views showing the process of a method of manufacturing the touch screen panel according to the second embodiment of the present invention.

### DESCRIPTION OF THE PREFERRED EMBODIMENTS

It should be noted that the same reference numerals are used throughout the different drawings to designate the same or similar components when reference is made to the components in the description. Further, if in the specification, detailed descriptions of well-known functions or configurations related to the present invention may unnecessarily make the gist of the present invention obscure, the detailed descriptions will be omitted.

Preferred embodiments of the present invention will be described in detail with reference to the accompanying drawings below.

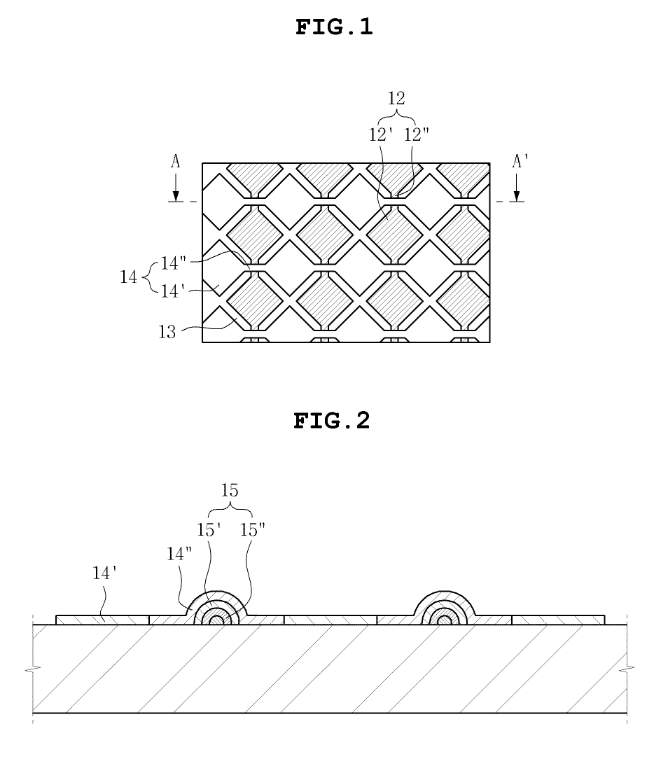

FIG. 1 is a plan view showing a touch screen panel according to a first embodiment of the present invention.

Referring to FIG. 1, detection patterns according to the first embodiment of the present invention include a plurality of first detection patterns 12 and a plurality of second detection patterns 14 which are alternately arranged. The first detection patterns 12 are formed for respective columns each having the same X coordinate. The second detection patterns 14 are formed for respective rows each having the same Y coordinate.

Further, each of the first detection patterns 12 includes first detection cells 12′ and first connection lines 12″. The first detection cells 12′ are arranged in each column along a first direction (column direction) having the same X coordinate. The first connection line 12″ is configured to connect first detection cells 12′ which are adjacent to each other. Each of the second detection patterns 14 includes second detection cells 14′ and second connection lines 14″. The second detection cells 14′ are arranged in each row along a second direction (row direction) having the same Y coordinate. The second connection lines 14″ are configured to connect the second detection cells 14′ which are adjacent to each other.

Here, in the first embodiment of the present invention, the first detection patterns 12 and the second detection patterns 14 are formed in the same layer on a substrate 11, and an insulation layer 13 is formed on the first and second detection patterns 12 and 14.

Further, the substrate 11 and the first and second detection patterns 12 and 14 should be implemented using transparent materials in order to implement the operation of the touch screen panel, so that it is preferable that the first and second detection patterns 12 and 14 be made of a conductive polymer, such as Indium-Tin Oxide (hereinafter, referred to as ITO), PolyEthyleneDiOxyThiophene (PEDOT), or ProtActinium (PA).

In order for the first detection patterns 12 and the second detection patterns 14 to function as detection electrodes, the detection cells arranged in the first direction should be electrically connected, and the detection cells arranged in the second direction should be electrically connected.

Here, the first detection cells 12′ are electrically connected with each other by the first connection lines 12″. However, since the second detection cells 14′ which constitute part of the second detection patterns 14 are formed in the same layer as the first detection cells 12′, a connection line which directly intersects any of the first connection lines 12′ cannot be formed in order to avoid a short-circuit related to the first connection line 12′.

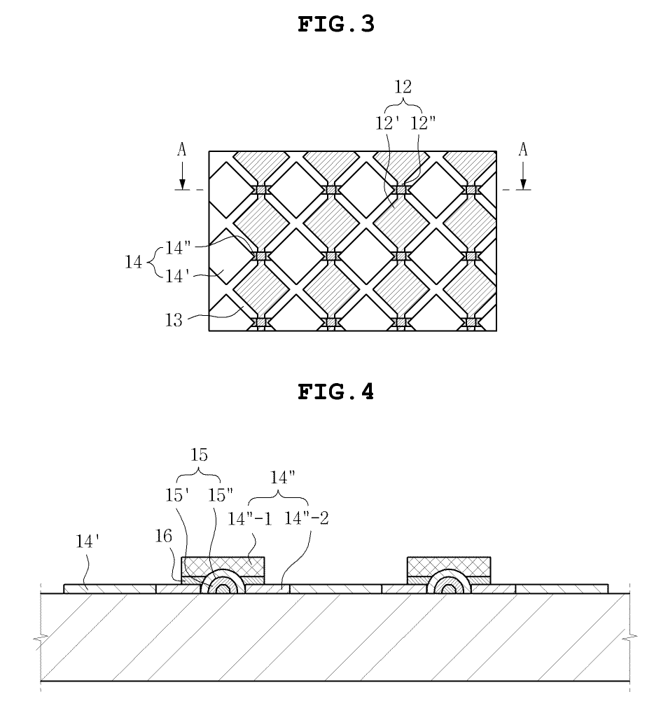

Therefore, as shown in FIG. 2 showing the section taken along line A-A′ of FIG. 1, in the first embodiment of the present invention, in order to prevent electrical connection from being made between each of the first connection lines 12″ of the first detection patterns 12 and a corresponding second connection line 14″ connecting second detection cells 14′, the first connection line 12″ and the second connection line 14″ are formed to intersect each other with a connection prevention layer 15 formed to enclose the first connection line 12″ being interposed therebetween.

If each of the first connection lines 12″ and a corresponding second connection line 14″ are formed to intersect each other with each of the connection prevention layers 15 interposed therebetween, as described above, space can be effectively used while electrical connection is not made.

Further, if the connection prevention layer 15 is made of an insulation material with high dielectric strength, parasitic capacitance generated by the intersection of the first connection line 12″ and the second connection line 14″ can be minimized.

Of course, in order to minimize the parasitic capacitance generated by the intersection of the first connection line 12″ and the second connection line 14″, the width of the second connection line 14″ may be additionally reduced. If the width of the second connection line 14″ is additionally reduced, resistance decreases, thereby improving sensing sensitivity.

Here, the connection prevention layer 15 is formed of a dual layer. The outer layer thereof is formed of an insulation layer 15′ which is made of an insulation material for providing electrical insulation, and the inner layer thereof is made of an adhesive material with an adhesive property so that it is attached to the first connection line 12″ in a process of forming the insulation layer 15′ and is made of a non-conductive adhesive layer 15″ with non-conductivity.

If the above-described dual-structured connection prevention layer 15 is used, sufficient electrical insulation and desired adhesive strength can be provided.

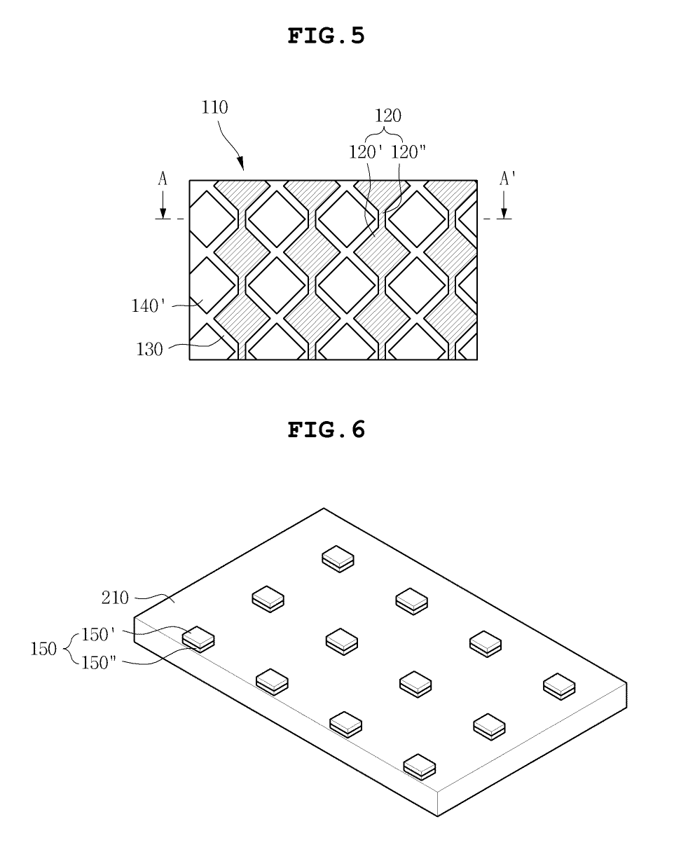

FIG. 3 is a plan view showing a touch screen according to a second embodiment of the present invention.

Referring to FIG. 3, the detection patterns according to the second embodiment of the present invention include a plurality of first detection patterns 12 and a plurality of second detection patterns 14 which are alternatively arranged. The first detection patterns 12 are connected with each other for each column having the same X coordinate. The second detection patterns 14 are connected to each other for each row having the same Y coordinate.

Further, each of the first detection patterns 12 includes a first detection cell 12′ and a first connection line 12″. The first detection cell 12′ is arranged in a single column along a first direction (column direction) having the same X coordinate. The first connection line 12″ is configured to connect first detection cells 12′ which are adjacent to each other. Each of the second detection patterns 14 includes a second detection cell 14′ and a second connection line 14″. The second detection cell 14′ is arranged in a single row along a second direction (row direction) having the same Y coordinate. The second connection line 14″ is configured to connect second detection cells 14′ which are adjacent to each other.

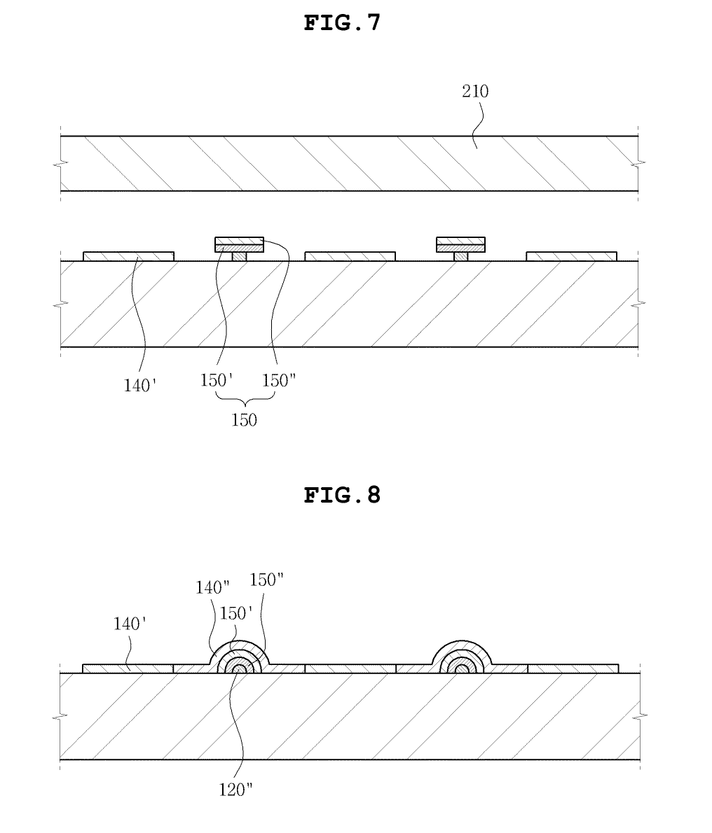

Here, as shown in FIG. 4 showing the sectional view taken along line B-B′ of FIG. 3, in the second embodiment of the present invention, in order to prevent electrical connection from being made between the first connection line 12″ of each of the first detection patterns 12 and a corresponding second connection lines 14″ connecting the second detection cells 14′ with another second detection cell 14′, the first connection line 12″ and the second connection line 14″ are formed to intersect each other with a connection prevention layer 15 formed to enclose the first connection line 12″ being interposed therebetween.

Further, the second connection line 14″ includes two sections, that is, a bridge connection line 14″-1 formed to enclose the connection prevention layer 15 in a bridge shape, and a coupling line 14″-2 configured to have one end connected to the bridge connection line 14″-1 and the other end connected to one of the second detection cells 14′.

If the second connection line 14″ is configured to include two sections as described above, each section can be manufactured using processes, which are different from each other, in the manufacturing process, so that the time and expense of the manufacturing process can be reduced.

The width of the bridge connection line 14″-1 may be the same as or different from the width of the coupling line 14″-2, and the same material or different materials may be used for them.

Further, the bridge connection line 14″-1 and the coupling line 14″-2 are made of adhesive materials, and may be attached to each other using a conductive adhesive layer 16 with electrical conductivity.

Here, the connection prevention layer 15 is formed with a dual layer. The outer layer thereof is formed by an insulation layer 15′ which is made of an insulation material for providing electrical insulation, and the inner layer thereof is made of an adhesive material with an adhesive property so that it is attached to the first connection line 12″ in a process of forming the insulation layer 15′ and is formed of a non-conductive adhesive layer 15″ with non-conductivity.

If the above-described dual-structured connection prevention layer 15 is used, sufficient electrical insulation and desired adhesive strength can be provided.

Meanwhile, since the configurations and operations of the other parts of the touch screen panel according to the second embodiment are the same as those of the touch screen panel according to the first embodiment, the detailed descriptions thereof will be omitted.

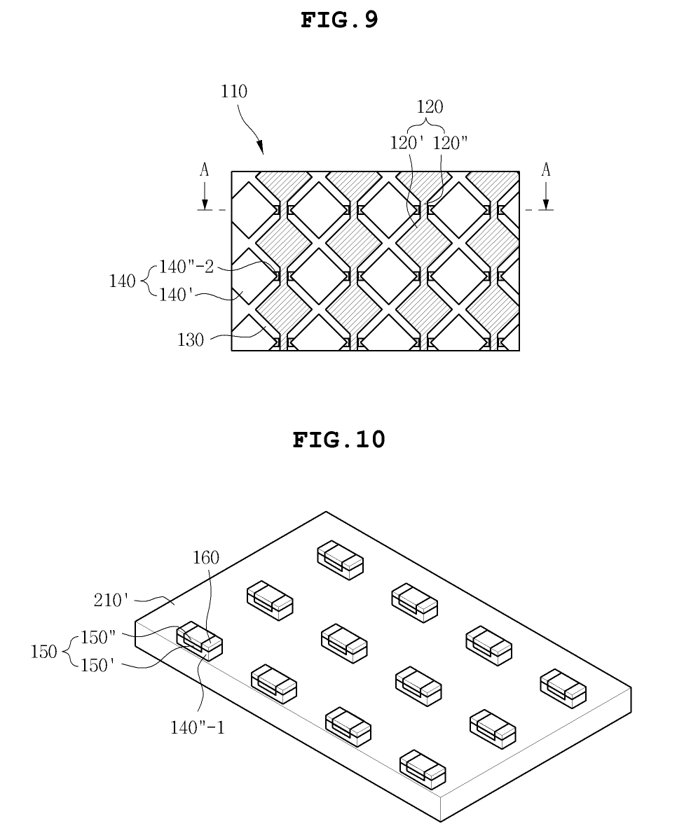

FIGS. 5 to 8 are views showing the process of a method of manufacturing the touch screen panel according to the first embodiment of the present invention.

First, as shown in FIG. 5, a transparent substrate 110 is provided which includes a plurality of first detection patterns 120 and a plurality of second detection patterns 140 which are alternately arranged. The first detection patterns 120 are connected with each other for each column having the same X coordinate. The second detection patterns 140 are connected with each other for each single row having the same Y coordinate.

Here, each of the first detection patterns 120 includes a first detection cell 120′ and a first connection line 120. The first detection cell 120′ is arranged in a single column along a first direction (column direction) having the same X coordinate. The first connection line 120″ is configured to connect first detection cells 120′ which are adjacent to each other. Each of the second detection patterns 140 includes a second detection cell 140′ arranged in a single row along the second direction (row direction) having the same Y coordinate.

Further, as shown in FIG. 6, a rectangular plate-shaped release film 210 is provided as a transporter. The release film 210 includes a plurality of insulation layers 150 and a plurality of adhesive layers 150′. Each of the insulation layers 150 is separated at a predetermined and formed at a location corresponding to the each first connection line 120″ of the first detection pattern 120. Each of he adhesive layers 150′ is formed on the insulation layer 150″.

Thereafter, as shown in FIG. 7, the release film 210 is turned over and layered on the transparent substrate 110 so that the adhesive layer 150′ is attached on the corresponding first connection line 120″ and the insulation layer 150″ is layered on the corresponding first connection line 120″, and then the release film 210 is removed.

Next, as shown in FIG. 8, the second connection line 140″ connecting second detection cells 140′ is formed to intersect the corresponding first connection line 120″ of the first detection pattern 120 with a connection prevention layer 150, formed to prevent the electrical connection from being made, being interposed therebetween.

Of course, although the process of forming such a second connection line 140″ has not been shown, the process is realized in such a way that a dry film is layered, patterning and metal plating are performed, and then the dry film is removed.

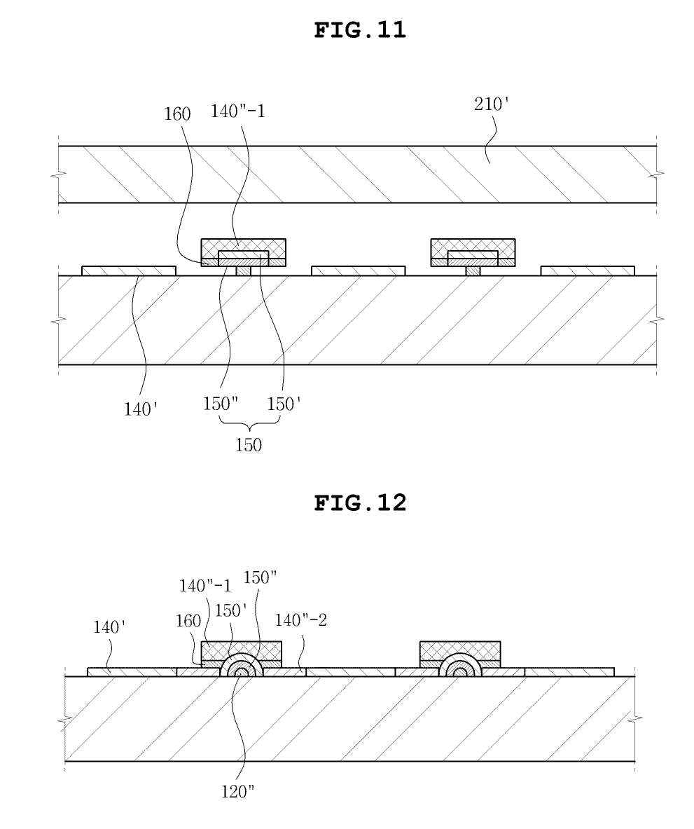

FIGS. 9 to 12 are views showing the process of a method of manufacturing the touch screen panel according to the second embodiment of the present invention.

First, as shown in FIG. 9, a transparent substrate 110 is provided which includes a plurality of first detection patterns 120 and plurality of second detection patterns 140 which are alternately arranged. The first detection patterns 120 are connected with each other for each column having the same X coordinate. The second detection patterns 140 are connected for each row having the same Y coordinate.

Here, each of the first detection patterns 120 includes a first detection cell 120′ and a first connection line 120″. The first detection cell 120′ is arranged in a single column along a first direction (column direction) having the same X coordinate. The first connection line 120″ is configured to connect first detection cells 120′ which are adjacent to each other. Each of the second detection patterns 140 includes a second detection cell 140′ and a coupling line 140″-2. The second detection cell 140′ is arranged in a single row along a second direction (row direction) having the same Y coordinate. The coupling line 140″-2 is configured to form the second connection line connecting second detection cells 140′ which are adjacent to each other.

Here, the coupling line 140″-2 is formed to protrude and be extended at the both right and left ends of each of the second detection cells 140′, and electrically connected to each other by the following process.

Next, as shown in FIG. 10, a rectangular plate-shaped release film 210 is provided. The release film 210 includes a plurality of bridge connection lines 140″-1, a plurality of insulation layers 150′, a plurality of conductive adhesive layers 160, and a plurality of adhesive layers 150″. Each of the bridge connection lines 140″-1 is separated at a predetermined interval from each other, formed at a location corresponding to the each first connection line 120″ of the first detection pattern 120, and configured to have a depression. Each of the insulation layers 150′ is formed in the depression of the bridge connection line 140″-1. Each of the conductive adhesive layers 160 is layered on the both ends of the bridge connection line 140″-1. Each of the adhesive layers 150″ is formed on the corresponding insulation layer 150′.

Thereafter, as shown in FIG. 11, the release film 210′ is turned over and layered on the transparent substrate 110 so that the adhesive layer 150″ is attached on the corresponding first connection line 120″ and the insulation layer 150′ is layered on the corresponding first connection line 120″. Thereafter, as shown in FIG. 12, the conductive adhesive layer 160 adheres to the corresponding coupling line 140″-2 so that the bridge connection line 140″-1 is electrically connected to the coupling line 140″-2 located in both sides thereof with the bridge connection line 140″-1 being layered on the corresponding first connection line 120″, and then the release film 210′ is removed.

As described above, when the release film 210′ is removed, each of the second connection lines 140″ connecting the second detection cells 140′ is formed to intersect the corresponding first connection line 120″ of the first detection pattern 120 with a connection prevention layer 150, formed to prevent the electrical connection from being made, being interposed therebetween.

According to the above-described present invention, there is an advantage of preventing a decrease in sensing sensitivity with regard to the first detection patterns and the second detection patterns which are formed in the same layer by removing a mask process of forming connection patterns which connect the first and second detection patterns and by reducing parasitic capacitance generated at an intersection.

Although the preferred embodiments of the present invention have been disclosed above for illustrative purposes, the present invention is not limited thereto. Those skilled in the art will appreciate that various modifications are possible, without departing from the gist of the invention as disclosed in the accompanying claims, and the modification should not be interpreted as separately from the technical spirit of the present invention.

What is claimed is:

1. A touch screen panel, comprising:
a substrate;
a plurality of first detection patterns, each formed on the substrate, configured to comprise a plurality of first detection cells which are arranged in a single column along a first direction having a same coordinate, and a plurality of first connection lines which connect first detection cells which are adjacent to each other;
a plurality of second detection patterns, each formed on the substrate, configured to comprise a plurality of second detection cells which are arranged in a single row along a second direction having a same coordinate, and a plurality of second connection lines which connect second detection cells which are adjacent to each other; and
a plurality of connection prevention layers, each located between each of the first connection lines and each of the second connection lines at an intersection where the first connection line of the first detection pattern intersects the second connection line of the second detection pattern, and each made of an electrical insulation material.

2. The touch screen panel as set forth in claim 1, wherein the connection prevention layer comprises:
a first adhesive layer formed to enclose the first connection line and made of a non-conductive adhesive material; and
an insulation layer layered on the first adhesive layer, and configured to have a surface on which the second connection line is formed and which is away from a surface which comes into contact with the first adhesive layer.

3. The touch screen panel as set forth in claim 1, wherein the second connection line comprises:
a bridge-shaped bridge connection line formed to enclose the connection prevention layer; and
a coupling line configured to have one end which is connected to the bridge connection line and another end which is connected to one of the second detection cells.

4. The touch screen panel as set forth in claim 3, further comprising a second adhesive layer configured to attach the bridge connection line to the coupling line with conductivity.

5. The touch screen panel as set forth in claim 1, wherein the second detection cells are alternately arranged with the first detection cells so that each of the second detection cells is not superimposed on the corresponding first detection cell.

6. The touch screen panel as set forth in claim 1, wherein the first and second detection patterns are made of a transparent electrode material.

7. The touch screen panel as set forth in claim 6, wherein the transparent electrode is made of a conductive polymer.

8. A method of manufacturing a touch screen panel, the method comprising:
(A) preparing a substrate configured to include a plurality of first detection cells, a plurality of first connection lines connecting first detection cells which are adjacent to each other, and a plurality of second detection cells which are alternately arranged with the first detection cells;
(B) preparing a plate-shaped transporter configured to include a plurality of connection prevention layers separated at a predetermined interval from each other, and formed at locations corresponding to the respective first connection lines;
(C) layering the connection prevention layers of the transporter on the respective first connection lines of the substrate; and
(D) forming a plurality of second connection lines each configured to connect second detection cells so that the second connection line intersects the corresponding first connection line with each of the connection prevention layers being interposed therebetween.

9. The method as set forth in claim 8, wherein the (B) of preparing the transporter comprises:
(B-1) preparing the plate-shaped transporter;
(B-2) layering a plurality of insulation layers on the transporter, the insulation layers constituting the connection prevention layer which is formed in the plate shape, separated at the predetermined interval from each other, and formed at a location corresponding to the first connection line; and
(B-3) forming a plurality of adhesive layer on the insulation layers, the adhesive layers constituting the connection prevention layer.

10. The method as set forth in claim 8, wherein the (C) of layering the connection prevention layers comprises:
(C-1) allowing the connection prevention layer of the transporter to face the corresponding first connection line of the substrate;
(C-2) layering the connection prevention layer of the transporter on the first connection line of the substrate; and
(C-3) removing the transporter.

11. A method of manufacturing a touch screen panel, the method comprising:
(A) preparing a substrate configured to include a plurality of first detection cells, a plurality of first connection lines connecting the first detection cells which are adjacent to each other, and a plurality of second detection cells being alternately arranged with the first detection cells and including conjunctive lines which protrude toward each other;
(B) preparing a transporter configured to include a plurality of bridge connection lines, each of the bridge connection lines being formed in a bridge shape and having a depression, being separated at a predetermined interval from each other, including a connection prevention layer on the depression, and being formed at a location corresponding to each of the first connection lines; and
(C) layering the connection prevention layer of the transporter on the first connection line of the substrate, and connecting the bridge connection line to the corresponding conjunctive line with the bridge connection line enclosing the connection prevention layer.

12. The method as set forth in claim 11, wherein the (B) of preparing the transporter comprises:
(B-1) preparing the plate-shaped transporter;
(B-2) layering the plurality of bridge connection lines on the transporter, each of the bridge connection lines being formed in the bridge shape, being separated at the predetermined interval from each other, being formed at the location corresponding to the first connection line, and having the depression;
(B-3) forming an insulation layer constituting the connection prevention layer in the depression of the bridge connection line;
(B-4) forming an adhesive layer constituting the connection prevention layer on the insulation layer; and
(B-5) forming conductive adhesive layers on both ends of the bridge connection line.

13. The method as set forth in claim 11, wherein the (C) of layering the connection prevention layer comprises:
(C-1) allowing the connection prevention layer of the transporter to face the corresponding first connection line of the substrate;
(C-2) layering the connection prevention layer of the transporter on the first connection line of the substrate so that the bridge connection line is connected to the conjunctive line with the bridge connection line enclosing the connection prevention layer; and
(C-3) removing the transporter.
